(19) United States
(12) Patent Application Publication
(10) Pub. No.: US 2017/0179913 A1
(43) Pub. Date: Jun. 22, 2017

(54) COMMON MODE FILTER

(71) Applicant: SAMSUNG ELECTRO-MECHANICS CO., LTD., Suwon-si (KR)

(72) Inventors: Ha Yoon SONG, Suwon-si (KR); Jong Yun LEE, Suwon-si (KR); Sung Ryong MA, Suwon-si (KR); Won Chul SIM, Suwon-si (KR); Young Seuck YOO, Suwon-si (KR); Byoung Hwa LEE, Suwon-si (KR); Young Jae KIM, Suwon-si (KR); Tae Chul HA, Suwon-si (KR); Hye Won BANG, Suwon-si (KR)

(21) Appl. No.: 15/248,535

(22) Filed: Aug. 26, 2016

(30) Foreign Application Priority Data
Dec. 22, 2015 (KR) 10-2015-0184043

(51) Int. Cl. H03H 1/00; H01F 27/245; H01F 27/29; H01F 27/28

(52) U.S. Cl. CPC H03H 1/0007; H01F 27/2804; H01F 27/245; H01F 27/292; H01F 2027/2809; H03H 2001/0085; H03H 2001/0092; H03H 2001/0057

(57) ABSTRACT

A common mode filter includes: a coil part including a plurality of coil layers, each coil layer having at least one coil and a lead terminal connected to a first end of the coil, and a conductive via connecting the lead terminals to each other; a first magnetic layer disposed on the coil part; a second magnetic layer disposed below the coil part; and external electrodes connected to the lead terminals and exposed to the surface of the common mode filter.

### CROSS-REFERENCE TO RELATED APPLICATION(S)

This application claims the benefit of priority to Korean Patent Application No. 10-2015-0184043, filed on Dec. 22, 2015 with the Korean Intellectual Property Office, the entirety of which is incorporated herein by reference.

### TECHNICAL FIELD

The present disclosure relates to a common mode filter.

### BACKGROUND

In accordance with the development of technology, an electronic device may be changed from an analog type to a digital type, and a high speed interface may be applied to the electronic device due to an increase in the amount of processed data. As the high speed interface, a universal serial bus (USB) 2.0, a USB 3.0, and a high-definition multimedia interface (HDMI) have widely spread, and the above-mentioned interfaces are currently used in many digital electronic devices such as smartphones, personal computers, and digital high-definition televisions.

These high speed interfaces may employ a differential signal system that transmits differential signals (differential mode signals) using a pair of signal lines, in contrast to single-end transmitting systems that have generally been used in the related art. However, since the electronic devices that are digitized and have an increased speed are sensitive to outside stimuli, signal distortion due to high frequency noise often occurs.

Examples of the cause of abnormal voltage and noise include a switching voltage generated in a circuit, power noise included in a power supply voltage, unnecessary electromagnetic signals, electromagnetic noise, and the like. A common mode filter (CMF) may be used as a means for preventing the above-mentioned abnormal voltage and high frequency noise from being introduced into the circuit.

### SUMMARY

An aspect of the present disclosure provides a common mode filter capable of preventing deterioration by thermal, electrical, and physical stress by enhancing adhesion between external electrodes and coil layers. Further, an aspect of the present disclosure provides a common mode filter which may be protected from static electricity.

According to an aspect of the present disclosure, a common mode filter includes a coil part including a plurality of coil layers having one or more coils and lead terminals connected to one end of each of the coils, and a conductive via connecting the lead terminals to each other; a first magnetic layer disposed on the coil part; a second magnetic layer disposed below the coil part; and external electrodes connected to the lead terminals and exposed to the outside.

According to another aspect of the present disclosure, a common mode filter includes a coil part including a plurality of coil layers on which one or more coils and lead terminals connected to one end of each of the coils are formed, and a conductive via connecting the lead terminals of the plurality of coil layers to each other; a first magnetic layer disposed on the coil part; a second magnetic layer disposed below the coil part; external electrodes connected to the lead terminals; one or more ground electrodes exposed to the outside; and an electrostatic discharge (ESD) preventing layer disposed below the coil part and connected to the external electrodes and the one or more ground electrodes to discharge a high level of voltage applied to the external electrodes to the one or more ground electrodes.

### BRIEF DESCRIPTION OF DRAWINGS

FIG. 1 is a perspective view illustrating an example of a common mode filter;

FIG. 2 is an exploded perspective view of a coil part of FIG. 1;

FIG. 3 is a cross-sectional view taken along line I-I′ of FIG. 1;

FIG. 4, which is a cross-sectional view taken along line I-I′ of FIG. 1, illustrates a coil part according to another exemplary embodiment;

FIG. 5 is a perspective view a common mode filter according to another exemplary embodiment; and

FIG. 6 is a perspective view of an electrostatic discharge (ESD) preventing layer.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no other elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the embodiments.

Spatially relative terms, such as “above,” “upper,” “below,” and “lower” and the like, may be used herein for ease of description to describe one element's relationship relative to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” relative to other elements would then be oriented “below,” or “lower” relative to the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein describes particular embodiments only, and the present disclosure is not limited thereby. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments will be described with reference to schematic views. In the drawings, for example, due to manufacturing techniques and/or tolerances, modifications of the shape shown may be estimated. Thus, embodiments should not be construed as being limited to the particular shapes of regions shown herein, for example, to include a change in shape results in manufacturing. The following embodiments may also be constituted by one or a combination thereof.

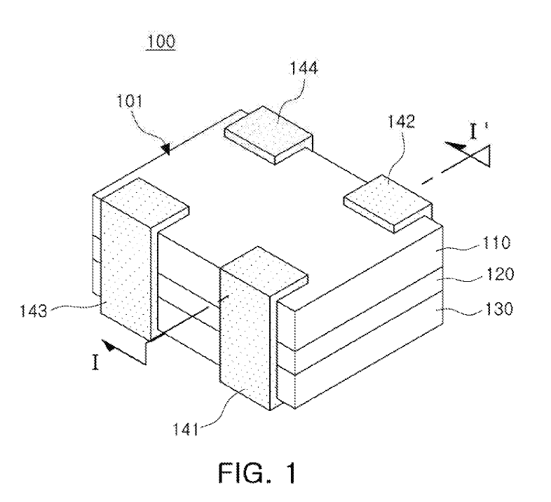

Referring to FIGS. 1 through 3, a common mode filter 100 includes a magnetic body 101 and first to fourth external electrodes 141, 142, 143, and 144. The magnetic body 101 may include first and second magnetic layers 110 and 130, and a coil part 120.

The first and second magnetic layers 110 and 130 may be formed of a magnetic ceramic material.

The first magnetic layer 110 refers to an upper magnetic sheet disposed on the coil part 120, and the second magnetic layer 130 refers to a lower magnetic sheet disposed below the coil part 120.

For example, the first and second magnetic layers 110 and 130 may be a ferrite sheet formed of a magnetic ceramic material, or may also be a sheet including a magnetic resin composite. When the first and second magnetic layers 110 and 130 are formed using a magnetic resin composite, flexibility may be provided to the first and second magnetic layers 110 and 130, thereby preventing an occurrence of cracks.

The first to fourth external electrodes 141, 142, 143, and 144 may be extend in a thickness direction of the magnetic body 101. Further, the first to fourth external electrodes 141, 142, 143, and 144 may be disposed to be spaced apart from each other.

The first to fourth external electrodes 141, 142, 143, and 144 may be formed of an electrically conductive metal. For example, the external electrodes may include one or more selected from the group consisting of gold (Au), silver (Ag), tin (Sn), platinum (Pt), copper (Cu), nickel (Ni), palladium (Pd), and alloys thereof.

The coil part 120 may include a plurality of coil layers having one or more coils and lead terminals connected to one end of each of the coils.

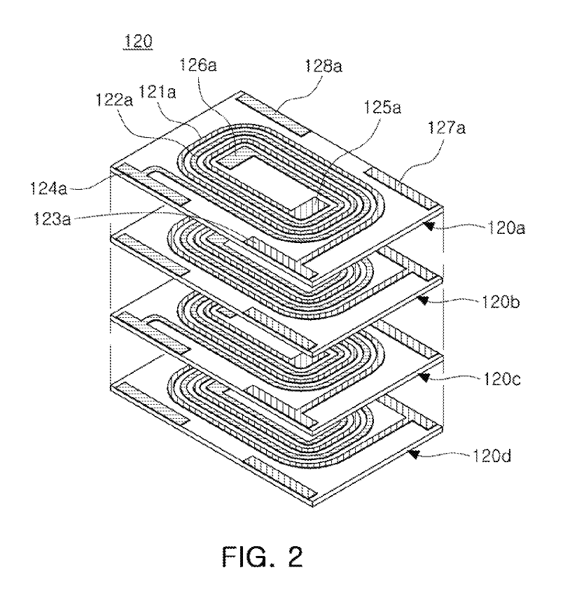

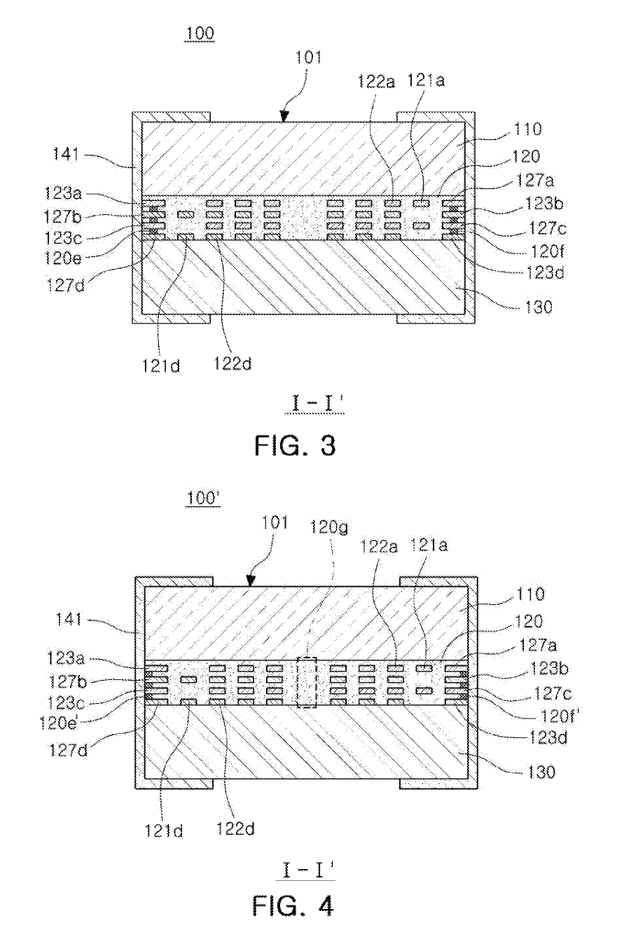

Although FIGS. 2 and 3 illustrate that the coil part includes first to fourth coil layers 120a, 120b, 120c, and 120d, the number of coil layers may be changed.

Hereinafter, the first coil layer 120a of the first to fourth coil layers 120a, 120b, 120c, and 120d included in the coil part 120 will be described with reference to FIG. 2.

The first coil layer 120a may include a first coil 121a and a second coil 122a which are wound to be parallel with each other in the same direction on the same plane.

The first and second coils 121a and 122a may be formed by winding a pattern formed of a conductive material one or more times on a ferrite layer, and may be formed by using a conductive paste, a photoresist method, and the like.

One end of each of the first and second coils 121a and 122a may be respectively connected to first and second lead terminals 123a and 124a, and the first and second lead terminals 123a and 124a may be exposed to an end surface of the magnetic body 101.

When the first and second coils 121a and 122a are directly connected to the external electrodes 141 and 143, since the first and second coils 121a and 122a may have a small width or thickness of a pattern, cross-sectional areas of connection portions between the first and second coils 121a and 122a and the external electrodes 141 and 143 may be small. As a result, the first and second coils 121a and 122a and the external electrodes 141 and 143 may not be smoothly connected to each other.

The cross-sectional areas at which the first and second coils 121a and 122a and the external electrodes 141 and 143 are connected may be increased by the first and second lead terminals 123a and 124a.

The other end of each of the first and second coils 121a and 122a may be connected to first and second internal terminals 125a and 126a, and the first and second internal terminals 125a and 126a may be connected to one or more of the other coil layers 120b, 120c, and 120d through an internal via.

The first coil layer 120a may further include dummy terminals 127a and 128a.

The dummy terminals 127a and 128a may each be connected to one of the first to fourth external electrodes 141, 142, 143, and 144.

A configuration of the second to fourth coil layers 120b, 120c, and 120d may be the same as that of the first coil layer 120a.

The coil part 120 may be formed by stacking and compressing the first to fourth coil layers 120a, 120b, 120c, and 120d.

Further, the coil part 120 may include conductive vias 120e and 120f connecting the lead terminals formed on the plurality of coil layers 120a, 120b, 120c, and 120d to each other. The conductive vias 120e and 120f may be formed by forming via holes by a laser punching or mechanical punching method, and filling the via holes with a conductive material.

Referring to FIG. 3, the lead terminal 123a of the first coil layer 120a may be connected to the lead terminal 123c of the third coil layer 120c through a first conductive via 120e.

Further, the first conductive via 120e may be connected to a dummy terminal 127b of the second coil layer 120b and a dummy terminal 127d of the fourth coil layer 120d.

Accordingly, even in a case in which a contact between the first external electrode 141 and any one lead terminal is disconnected by thermal, electrical, or physical stress, an electrical connection between the first external electrode 141 and the lead terminal may be maintained through the first conductive via 120e.

Similar to the first conductive via 120e described above, a second conductive via 120f may connect lead terminals 123b and 123d which are adjacent to the second external electrode 142 to each other. Further, the second conductive via 120f may connect the lead terminals 123b and 123d and the dummy terminals 127a and 127c to each other.

Although not illustrated in FIG. 3, there may also be a conductive via formed at the third external electrode 143 and the fourth external electrode 144 in the same scheme.

Referring to FIG. 4, a common mode filter 100′ in which first and second conductive vias 120e′ and 120f′ are modified, as compared to the common mode filter 100 illustrated in FIG. 3, may be seen.

As illustrated in FIG. 4, a conductive material in the first and second conductive vias 120e′ and 120f′ is exposed, and thus the first and second conductive vias 120e′ and 120f′ may be in contact with the first and second external electrodes 141 and 142, respectively.

The first and second conductive vias 120e′ and 120f′ may be cut during a process of separating a mother substrate on which a plurality of magnetic bodies are formed, and thus the conductive material in the first and second conductive vias 120e′ and 120f′ may be exposed.

Thereafter, when the first and second external electrodes 141 and 142 are in contact with surfaces to which the conductive material in the first and second conductive vias 120e′ and 120f′ is exposed, cross-sectional areas at which the first and second conductive vias 120e′ and 120f′ and the first and second external electrodes 141 and 142 are connected to each other may be increased.

Accordingly, adhesion between the external electrodes and the coil layers may be further enhanced.

In addition, another example of the coil part 120′ further includes a core 120g formed at the center thereof. The core 120g may improve performance of the common mode filter 100′.

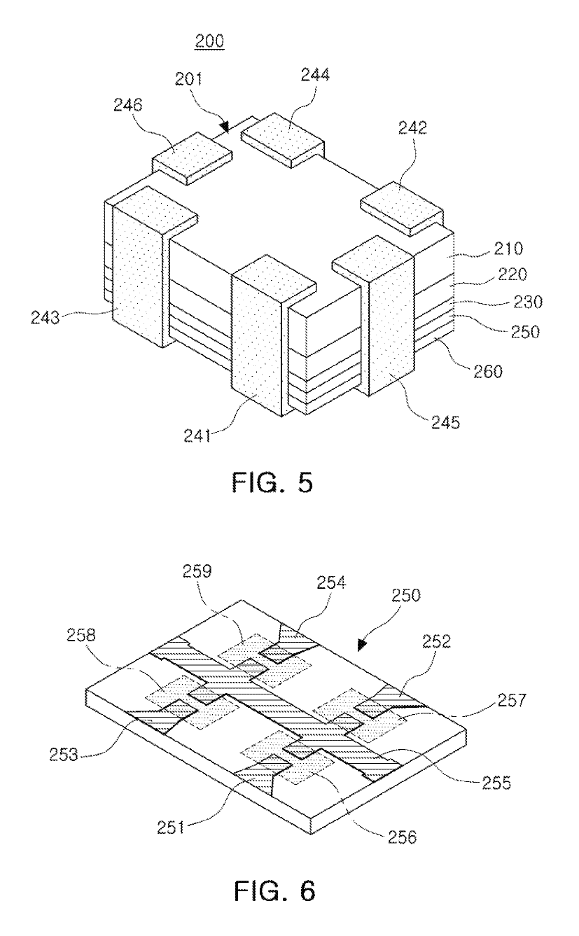

FIG. 5 is a perspective view of a common mode filter according to another exemplary embodiment, and FIG. 6 is a perspective view of an electrostatic discharge (ESD) preventing layer 250 included in the common mode filter shown in FIG. 5.

Referring to FIGS. 5 and 6, a common mode filter 200 that further includes first and second ground electrodes 245 and 246 externally exposed and an electrostatic discharge (ESD) preventing layer 250, as compared to the common mode filter 100 illustrated in FIGS. 1 through 3, may be seen.

The ESD preventing layer 250 may be disposed below a second magnetic layer 230 and a third magnetic layer 260 may be disposed below the ESD preventing layer 250, but the present exemplary embodiment is not limited thereto.

The ESD preventing layer 250 may be connected to first to fourth external electrodes 241, 242, 243, and 244 and also connected to first and second ground electrodes 245 and 246.

The ESD preventing layer 250 typically has insulation properties, but when a high voltage such as static electricity is applied to the ESD preventing layer 250, a current may flow therethrough. Therefore, the ESD preventing layer 250 may discharge the high voltage to the first and second ground electrodes 245 and 246, thereby preventing damage to the common mode filter 200.

In detail, the ESD preventing layer 250 may include discharge patterns 251, 252, 253, and 254 connected to first to fourth external electrodes 241, 242, 243, and 244, and a ground pattern 255 connected to the first and second ground electrodes 245 and 246.

Further, the discharge patterns 251, 252, 253, and 254 and the ground pattern 255 may be formed to be separated from each other, and ESD insulating pastes 256, 257, 258, and 259 may be applied to spaces between the discharge patterns 251, 252, 253, and 254 and the ground pattern 255.

As the ESD insulating pastes 256, 257, 258, and 259, pastes in which conductive metals such as copper (Cu), silver (Ag), and the like are dispersed in an insulating inorganic material or an insulating organic material such as Al₂O₃, TiO₂, ZnO, and the like may be used. The above-mentioned pastes are typically operated as a nonconductor, and when a high voltage such as static electricity is applied to the pastes, the current may flow in the pastes through a conductive metal.

Accordingly, the high voltage applied to the first through fourth external electrodes 241, 242, 243, and 244 may be discharged through the first or second ground electrode 245 or 246 connected to a ground.

Since other configurations and functions may be understood from the common mode filters 100 and 100′ described above with reference to FIGS. 1 through 4, an overlapping description will be omitted.

As set forth above, according to exemplary embodiments in the present disclosure, the common mode filter capable of preventing deterioration by thermal, electrical, and physical stress by enhancing adhesion between external electrodes and coil layers by the conductive via used for the lead terminals may be provided.

While exemplary embodiments have been shown and described above, it will be apparent to those skilled in the art that modifications and variations could be made without departing from the scope of the present invention as defined by the appended claims.

What is claimed is:

1. A common mode filter comprising:
a coil part including a plurality of coil layers, each coil layer having at least one coil and a lead terminal connected to a first end of the coil, and a conductive via connecting the lead terminals to each other;
a first magnetic layer disposed on the coil part;
a second magnetic layer disposed below the coil part; and
external electrodes connected to the lead terminals and exposed to the surface of the common mode filter.

2. The common mode filter of claim 1, wherein at least one of the coil layers among the plurality of coil layers includes a dummy terminal connected to one of the external electrodes, and
the conductive via connects the dummy terminal and at least one of the lead terminals to each other.

3. The common mode filter of claim 1, wherein a conductive material in the conductive via is exposed to one of the external electrodes, and the conductive via is in contact with the external electrodes.

4. The common mode filter of claim 1, wherein the coil part further includes a core formed at the center thereof.

5. The common mode filter of claim 1, wherein the coil layers each include a first coil and a second coil which are wound to be parallel with each other in the same direction on the same plane.

6. The common mode filter of claim 1, wherein the first and second magnetic layers are formed of a magnetic ceramic material.

7. A common mode filter comprising:
a coil part including a plurality of coil layers, each coil layer having at least one coil and a lead terminal connected to a first end of the coil, and a conductive via connecting the lead terminals to each other;
a first magnetic layer disposed on the coil part;
a second magnetic layer disposed below the coil part;
external electrodes connected to the lead terminals;
one or more ground electrodes exposed to the surface of the common mode filter; and
an electrostatic discharge (ESD) preventing layer disposed below the coil part and connected to the external electrodes and the one or more ground electrodes to discharge a high level of voltage applied to the external electrodes to the one or more ground electrodes.

8. The common mode filter of claim 7, wherein the ESD preventing layer includes discharge patterns connected to the external electrodes and ground patterns connected to the ground electrodes.

9. The common mode filter of claim 7, wherein at least one of the plurality of coil layers includes a dummy terminal connected to one of the external electrodes, and
the conductive via connects the dummy terminal and at least one of the lead terminals to each other.

10. The common mode filter of claim 7, wherein a conductive material in the conductive via is exposed to one of the external electrodes, and the conductive via is in contact with the external electrodes.

11. The common mode filter of claim 7, wherein the coil part further includes a core formed at the center thereof.

12. The common mode filter of claim 7, wherein the coil layers each include a first coil and a second coil which are wound to be parallel with each other in the same direction on the same plane.

13. The common mode filter of claim 8, further comprising an ESD insulating paste disposed between the discharge patterns and the ground patterns.

14. The common mode filter of claim 13, wherein the ESD insulating paste includes a conductive metal dispersed in an insulating inorganic material or an insulating organic material.
